(19) United States
(12) Patent Application Publication
(10) Pub. No.: US 2025/0331231 A1
(43) Pub. Date: Oct. 23, 2025

(54) SEMICONDUCTOR DEVICE

(71) Applicant: Samsung Electronics Co., Ltd., Suwon-si (KR)

(72) Inventors: Dahye KIM, Suwon-si (KR); Jae Hyun PARK, Suwon-si (KR); Jinchan YUN, Suwon-si (KR); Daihong HUH, Suwon-si (KR)

(21) Appl. No.: 18/922,511

(22) Filed: Oct. 22, 2024

(30) Foreign Application Priority Data
Apr. 19, 2024 (KR) 10-2024-0053018

(51) Int. Cl. H01L 29/417; H01L 29/06; H01L 29/423; H01L 29/775; H01L 29/786

(52) U.S. Cl. CPC H10D 30/6729; H10D 30/6735; H10D 30/43; H10D 30/6757; H10D 62/121

(57) ABSTRACT

A semiconductor device with improved device performance and reliability includes a substrate, an active pattern including a plurality of channel patterns disposed on substrate and vertically spaced apart from each other, a gate electrode surrounding the plurality of channel patterns, a lower source/drain pattern disposed on the substrate, and disposed on one side of the plurality channel patterns, an upper source/drain pattern spaced upward from the lower source/drain pattern, and sidewall spacers including a first sidewall spacer in contact with a first side surface of the lower source/drain pattern and defining the first side surface, and a second sidewall spacer in contact with a second side surface of the lower source/drain pattern and defining the second side surface, in which the first side surface and the second side surface are opposing side surfaces of the lower source/drain pattern.

### CROSS-REFERENCE TO RELATED APPLICATION

This application claims priority to Korean Patent Application No. 10-2024-0053018, filed in the Korean Intellectual Property Office on Apr. 19, 2024, the entire contents of which are hereby incorporated by reference.

### BACKGROUND

### Field

The present disclosure relates to a semiconductor device.

### Description of Related Art

A semiconductor device is a core component used to control or amplify an electrical signal in an electronic device, and various types of semiconductor devices may be manufactured. For example, a memory device may be mainly used to store and retrieve data, while a non-memory device may be used to control or amplify an electrical signal. The semiconductor device is a core component of an electronic device and plays an important role in various fields including computers, communication equipment, consumer electronics, etc.

With the development of industry, the performance and function requirements of the electronic devices are also increasing. Accordingly high-performance characteristics of the semiconductor devices are essentially required, and the degree of integration of the semiconductor devices is increasing to meet these requirements. Various methods for forming semiconductor devices having excellent performance and improved degree of integration are being studied.

### SUMMARY

Embodiments of the present disclosure provide a semiconductor device with improved electrical characteristics and reliability.

According to some aspects of the present disclosure, a semiconductor device may include a substrate, an active pattern including a plurality of channel patterns disposed on substrate and vertically spaced apart from each other, a gate electrode surrounding the plurality of channel patterns, a lower source/drain pattern disposed on the substrate, and disposed on one side of the plurality of channel patterns, an upper source/drain pattern spaced upward from the lower source/drain pattern, and a sidewall spacer including a first sidewall spacer in contact with a first side surface of the lower source/drain pattern and a second sidewall spacer in contact with a second side surface of the lower source/drain pattern, in which the first side surface and the second side surface may be opposing side surfaces of the lower source/drain pattern.

According to some aspects of the present disclosure, a semiconductor device may include a substrate, an active pattern including a lower pattern disposed on the substrate and a plurality of channel patterns spaced apart from each other, wherein the plurality of channel patterns may include a lower channel pattern disposed on the lower pattern and a first upper channel pattern disposed on the lower channel pattern, a gate electrode surrounding the lower channel pattern and the first upper channel pattern, a lower source/drain pattern disposed on the lower pattern, and disposed on one side of the lower channel pattern, an upper source/drain pattern disposed on one side of the first upper channel pattern, and sidewall spacers disposed on two opposing side surfaces of the lower source/drain pattern, in which at least one of the lower source/drain pattern and the upper source/drain pattern may include multiple epitaxial layers.

According to some aspects of the present disclosure, a semiconductor device may include a substrate, an active pattern including a lower pattern extending in a first direction and disposed on the substrate, and a plurality of channel patterns spaced apart from each other in a second direction perpendicular to the first direction, in which each of the channel patterns may include a lower channel pattern disposed on the lower pattern and an upper channel pattern disposed on the lower channel pattern, a gate electrode surrounding each of the lower channel pattern and the upper channel pattern, a lower source/drain pattern disposed on the lower pattern, and disposed on at least one side of the lower channel pattern, an upper source/drain pattern disposed on at least one side of the upper channel pattern, and a dielectric isolation layer isolating the lower source/drain pattern and the upper source/drain pattern from each other so that the lower source/drain pattern and the upper source/drain pattern are spaced from each other, and sidewall spacers including a first sidewall spacer in contact with a first side surface of the lower source/drain pattern and defining the first side surface, and a second sidewall spacer in contact with a second side surface of the lower source/drain pattern and defining the second side surface, in which the first side surface and the second side surface may be opposing side surfaces of the lower source/drain pattern, in which the first sidewall spacer and the second sidewall spacer may be disposed such that a horizontal distance between the first sidewall spacer and the second sidewall spacer decreases in a direction approaching a top of the first and second sidewall spacers, the lower source/drain pattern and the upper source/drain pattern may have different conductivity types, and at least one of the lower source/drain pattern and the upper source/drain pattern may include multiple epitaxial layers.

According to some aspects of the present disclosure, sidewall spacers are disposed on both sides of the lower source/drain pattern to limit the shape of the lower source/drain pattern to correspond to the channel width, thereby improving the performance of the semiconductor device.

According to some aspects of the present disclosure, by forming a heavily doped epitaxial layer of a constituent material (e.g., germanium (Ge)) that can apply strain to the channel patterns to surround the outer side/surface of a lightly doped epitaxial layer of the same constituent material that connects adjacent channel patterns, it is possible to prevent defects caused by the heavily doped epitaxial layer contacting the channel pattern and to improve the performance of semiconductor devices.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a plan view provided to explain a semiconductor device according to some aspects of the present disclosure;

FIG. 2 is a cross-sectional view taken along line A-A of FIG. 1;

FIG. 3 is a cross-sectional view taken along line B-B of FIG. 1;

FIG. 4 is a diagram provided to explain a semiconductor device according to some aspects of the present disclosure;

FIG. 5 is a diagram provided to explain a dielectric isolation layer according to some aspects of the present disclosure;

FIG. 6 is a diagram provided to explain a semiconductor device according to some aspects of the present disclosure;

FIG. 7 is a diagram provided to explain a semiconductor device according to some aspects of the present disclosure;

FIG. 8 is a diagram provided to explain a semiconductor device according to some aspects of the present disclosure;

FIG. 9 is a diagram provided to explain a semiconductor device according to some aspects of the present disclosure;

FIG. 10 is a diagram provided to explain a semiconductor device according to some aspects of the present disclosure;

FIG. 11 is a diagram provided to explain a semiconductor device according to some aspects of the present disclosure;

FIG. 12 is a diagram provided to explain a semiconductor device according to some aspects of the present disclosure;

FIG. 13 is an enlarged view provided to explain a region R of FIG. 12; and

FIGS. 14 to 30 are diagrams showing intermediate stages, which are provided to explain a method for manufacturing a semiconductor device according to some aspects of the present disclosure.

### DETAILED DESCRIPTION

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Hereinafter, example details for the practice of the present disclosure will be described in detail with reference to the accompanying drawings.

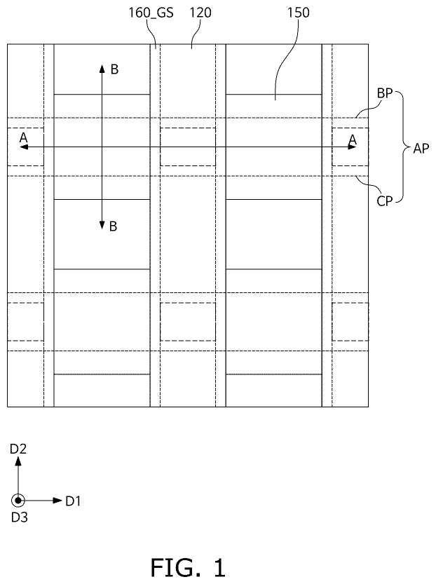

First, a semiconductor device according to some aspects of the present disclosure will be described with reference to FIGS. 1 to 3.

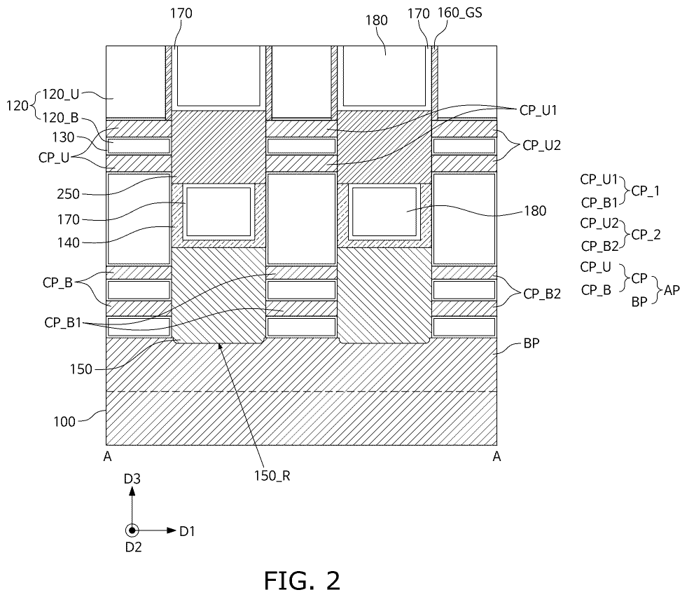

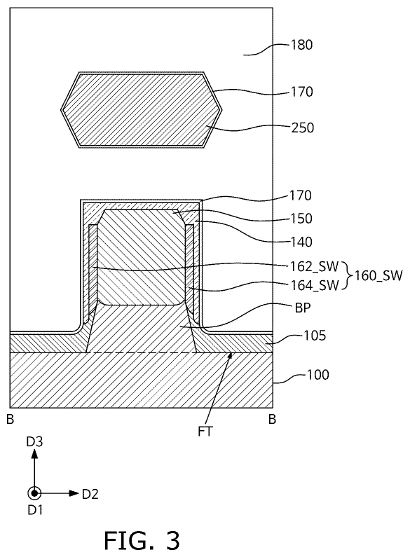

FIG. 1 is a plan view provided to explain a semiconductor device according to some aspects of the present disclosure. FIG. 2 is a cross-sectional view taken along line A-A of FIG. 1. FIG. 3 is a cross-sectional view taken along line B-B of FIG. 1.

Referring to FIGS. 1 to 3, a semiconductor device according to some aspects may include a substrate 100, an active pattern AP, a gate electrode 120, a gate insulating film 130, source and drain patterns 150 and 250, a sidewall spacer 160_SW, a dielectric isolation layer 140, and a gate spacer 160_GS. As used herein, each of the source and drain patterns 150 and 250 may be a pattern used as a source pattern and/or a drain pattern of a transistor, and may also be expressed as a source/drain pattern in the claims and/or in other parts of the present disclosure.

A semiconductor device according to some aspects may include a MOSFET, and for example, may include a gate-all-round (GAA) transistor and a three-dimensional multi-stack semiconductor device referred to as a multi-bridge channel FET (MBCFET). The three-dimensional multi-stack semiconductor device may be designed such that semiconductor channel regions of the n-type FET (nFET) and p-type FET (pFET) are stacked by placing one on the other.

The substrate 100 may be a bulk silicon or a silicon-on-insulator (SOI). On the other hand, the substrate 100 may include silicon germanium (SiGe), silicon germanium on insulator (SGOI), indium antimony, lead tellurium compound, indium arsenic, indium phosphide, gallium arsenic, or gallium antimony, but is not limited thereto.

The active pattern AP may be disposed on the substrate 100. The active pattern AP may extend, e.g., lengthwise, in a first direction D1. The active pattern AP may be spaced apart from adjacent active patterns AP in a second direction D2. In this case, the first direction D1 is a direction crossing (e.g., perpendicular to) the second direction D2. Each of the first and second directions D1 and D2 may be a direction parallel to an upper surface of the substrate 100.

The active pattern AP may be a multi-channel active pattern. The active pattern AP may include a lower pattern BP and a plurality of channel patterns CP.

The lower pattern BP may protrude from the substrate 100. The lower pattern BP may extend, e.g., lengthwise, in the first direction D1. The lower pattern BP may be spaced apart from adjacent lower patterns BP in the second direction D2. Lower patterns BP adjacent to each other may be separated by a field trench FT. The field trench FT may be defined by the upper surface of the substrate 100 and a side surface of the lower pattern BP.

A plurality of channel patterns CP may be disposed on the lower pattern BP. The plurality of channel patterns CP may be spaced apart from the lower pattern BP in a third direction D3. Each of the channel patterns CP may be spaced apart from each other in the third direction D3. The third direction D3 may be a direction crossing (e.g., perpendicular to) each of the first and second directions D1 and D2. The third direction D3 may be a direction perpendicular to the upper surface of the substrate 100. The third direction D3 may be a thickness direction of the substrate 100. Accordingly, the plurality of channel patterns CP may be disposed on the lower pattern BP of the substrate 100, and vertically spaced apart from each other. Each channel pattern CP may have a nanosheet shape.

The plurality of channel patterns CP may include a lower channel pattern CP_B and an upper channel pattern CP_U. The lower channel pattern CP_B may be disposed on the lower pattern BP, and the upper channel pattern CP_U may be disposed on the lower channel pattern CP_B. The lower channel pattern CP_B and the upper channel pattern CP_U may be of opposite conductivity types, but depending on designs, the lower channel pattern CP_B and the upper channel pattern CP_U may be of the same conductivity type. It is illustrated in FIG. 2 that channel pattern layers are two layers (e.g., the lower channel pattern CP_B and the upper channel pattern CP_U), but the inventive concept is not limited thereto. In addition, it is illustrated in FIG. 2 that there are two lower channel patterns CP_B and two upper channel patterns CP_U, but the inventive concept is not limited thereto.

The lower pattern BP may be formed by etching a part of the substrate 100. However, the inventive concept is not limited thereto. For example, the lower pattern BP may include an epitaxial layer grown from the substrate 100. The lower pattern BP may include an element semiconductor material such as silicon (Si) or germanium (Ge). In certain embodiments, the lower pattern BP may include a compound semiconductor. For example, the lower pattern BP may include a group IV-IV compound semiconductor or a group III-V compound semiconductor.

For example, the group IV-IV compound semiconductor may be a binary compound or a ternary compound including at least two of carbon (C), silicon (Si), germanium (Ge), and tin (Sn).

For example, the group III-V compound semiconductor may be one of a binary compound, a ternary compound, or a quaternary compound formed by a combination of at least one of aluminum (Al), gallium (Ga), and indium (In) as a group III element and one of phosphorus (P), arsenic (As), and antimony (Sb) as a group V element.

The channel pattern CP may include one of an element semiconductor material such as silicon (Si) or silicon germanium (SiGe), a group IV-IV compound semiconductor, or a group III-V compound semiconductor. Each of the plurality of channel patterns CP may include the same material as the lower pattern BP, or may include a material different from the lower pattern BP.

The lower pattern BP and the plurality of channel patterns CP may include silicon (Si). In some embodiments, the lower pattern BP and the plurality of channel patterns CP may include silicon germanium (SiGe). In certain embodiments, the lower pattern BP may include silicon (Si), and the plurality of channel patterns CP may include silicon germanium (SiGe).

A field insulating film 105 may be disposed on the substrate 100. The field insulating film 105 may fill a part of the field trench FT. The field insulating film 105 may be disposed between lower patterns BP adjacent to each other. The field insulating film 105 may extend, e.g., lengthwise, in the first direction D1. The field insulating film 105 may be formed on the upper surface of the substrate 100. The field insulating film 105 may cover a part of a sidewall of the lower pattern BP. For example, as illustrated in FIG. 3, the field insulating film 105 may cover the sidewall of the lower pattern BP, but may not be disposed on the upper surface of the lower pattern BP. For example, the field insulating film 105 may not be disposed between the upper surface of the lower pattern BP and the lower channel pattern CP_B.

For example, the field insulating film 105 may include an oxide, a nitride, a nitride oxide, or a combination thereof. Although it is illustrated in FIG. 3 that the field insulating film 105 is a single film, it is only for convenience of description, and the inventive concept is not limited thereto. For example, the field insulating film 105 may be formed of a plurality of films.

The source and drain patterns 150 and 250 may include a lower source and drain pattern 150 and an upper source and drain pattern 250. The lower source and drain pattern 150 and the upper source and drain pattern 250 may have opposite conductivity types. For example, the lower source and drain pattern 150 may have an n-type conductivity, and the upper source and drain pattern 250 may have a p-type conductivity. On the other hand, the lower source and drain pattern 150 may have a p-type conductivity, and the upper source and drain pattern 250 may have an n-type conductivity. In another example, the lower source and drain pattern 150 and the upper source and drain pattern 250 may have the same conductivity type.

The source and drain patterns 150 and 250 may be disposed in a source and drain trench 150_R extending, e.g., lengthwise, in the third direction D3. As used herein, the source and drain trench 150_R may be a trench in which one or more source/drain patterns are formed, and the source and drain trench 150_R may be expressed as a source/drain trench in the claims and/or in other parts of the present disclosure. The source and drain patterns 150 and 250 may fill at least a part of the source and drain trench 150_R. For example, the lower source and drain pattern 150 and the upper source and drain pattern 250 may respectively fill lower and upper portions of the source and drain trench 150_R. The dielectric isolation layer 140 isolating the lower and upper source and drain patterns 150 and 250 from each other may be included/formed between the lower source and drain pattern 150 and the upper source and drain pattern 250. For example, the dielectric isolation layer 140 may be interposed between the lower source/drain pattern 150 and the upper source/drain pattern 250 so that the lower source/drain pattern 150 and the upper source/drain pattern 250 are isolated (e.g., spaced apart) from each other.

A lower/bottom surface of a source and drain trench 150_R may be defined by the lower pattern BP. A side surface or sidewall of the source and drain trench 150_R in the first direction D1 may be defined by the sidewalls or side surfaces of the lower pattern BP, the channel pattern CP, and the gate insulating film 130. A side surface or sidewall of the source and drain trench 150_R in the second direction D2 may be defined by the sidewall spacer 160_SW.

The source and drain patterns 150 and 250 may be disposed on the active pattern AP and on at least one side of the active pattern AP.

For example, the lower source and drain pattern 150 may be disposed on the lower pattern BP. The lower source and drain pattern 150 may be disposed on at least one side of the lower channel pattern CP_B and electrically connected to the lower channel pattern CP_B. A part of the lower source and drain pattern 150 may be in contact with the channel pattern CP. Another part of the lower source and drain pattern 150 may be in contact with the gate insulating film 130. The lower source and drain pattern 150 may be disposed between the lower channel patterns CP_B spaced apart from each other in the first direction D1. The lower source and drain pattern 150 may connect the lower channel patterns CP_B of the channel pattern CP spaced apart from each other in the first direction D1. As used herein, components described as being “electrically connected” are configured such that an electrical signal can be transferred from one component to the other (although such electrical signal may be attenuated in strength as it is transferred and may be selectively transferred).

The upper source and drain pattern 250 may be disposed on at least one side of the upper channel pattern CP_U and electrically connected to the upper channel pattern CP_U. A part of the upper source and drain pattern 250 may be in contact with the upper channel pattern CP_U. Another part of the upper source and drain pattern 250 may be in contact with the gate insulating film 130. The upper source and drain pattern 250 may be disposed between the upper channel patterns CP_U spaced apart from each other in the first direction D1. The upper source and drain pattern 250 may connect the upper channel patterns CP_U of the channel pattern CP spaced apart from each other in the first direction D1.

The source and drain patterns 150 and 250 may be disposed on at least one side of the gate electrode 120. The source and drain patterns 150 and 250 may be disposed between the adjacent gate electrodes 120 in the first direction D1. For example, the source and drain patterns 150 and 250 may be disposed on both sides of a lower gate electrode 120_B. Unlike the illustration, the source and drain patterns 150 and 250 may be disposed on one side of the gate electrode 120 and may not be disposed on the other side of the gate electrode 120.

The source and drain patterns 150 and 250 may be epitaxial patterns formed by a selective epitaxial growth process using the active pattern AP as a seed. The source and drain patterns 150 and 250 may serve as sources and drains of transistors that use the channel patterns CP as channel regions. For example, the lower source and drain pattern 150 may serve as a source or a drain of a transistor that uses the lower channel pattern CP_B as a channel region, and the upper source and drain pattern 250 may serve as a source or a drain of a transistor that uses the upper channel pattern CP_U as a channel region.

The source and drain patterns 150 and 250 may include a semiconductor material. For example, the source and drain patterns 150 and 250 may include an element semiconductor material such as silicon (Si) or germanium (Ge). In some embodiments, the source and drain patterns 150 and 250 may include, for example, a binary compound or a ternary compound including at least two or more of carbon (C), silicon (Si), germanium (Ge), tin (Sn), or a compound of these doped with a group IV element. For example, the source and drain pattern 150 may include silicon (Si), silicon-germanium (SiGe), germanium (Ge), silicon carbide (SiC), etc., but is not limited thereto.

The source and drain patterns 150 and 250 may include impurities doped into the semiconductor material. The doped impurities may include at least one of boron (B), phosphorus (P), carbon (C), arsenic (As), antimony (Sb), bismuth (Bi), and oxygen (O), but the inventive concept is not limited thereto. The lower source and drain pattern 150 and the upper source and drain pattern 250 may have opposite conductivity types, and may include the same or different semiconductor materials. For example, the source and drain patterns with p-type conductivity may include silicon-germanium (SiGe), boron-doped silicon-germanium (SiGe:B), carbon-doped silicon-germanium (SiGe:C), carbon and boron-doped silicon-germanium (SiGe:C:B), boron-doped silicon (Si:B), and silicon (Si). Source and drain patterns with n-type conductivity may include phosphorus-doped silicon (Si:P), arsenic-doped silicon (Si:As), carbon-doped silicon (Si:C), arsenic and carbon-doped silicon (Si:As:C), arsenic and phosphorus-doped silicon (Si:As:P), and silicon (Si). However, the inventive concept is not limited thereto.

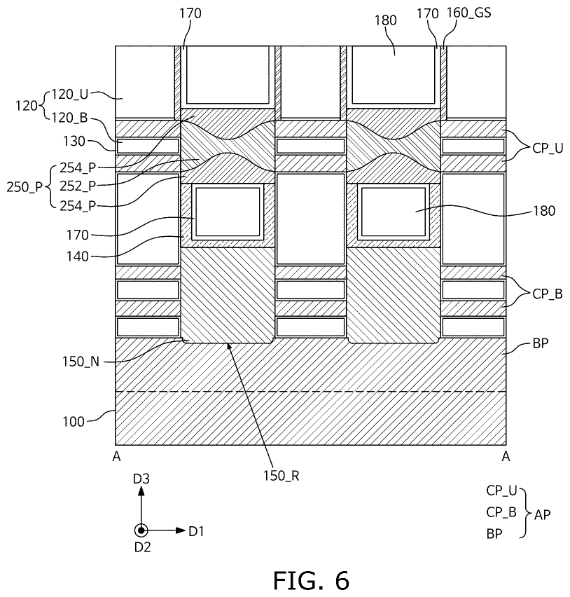

Although it is illustrated in FIG. 2 that the source and drain patterns 150 and 250 are single films, it is only for convenience of description, and the inventive concept is not limited thereto. For example, each source and drain pattern may include a plurality of layers including different materials. In some embodiments, the source and drain pattern may include the same material and may include a plurality of layers having different concentrations of constituent materials (e.g., concentrations of germanium (Ge)). Examples will be described in detail below with reference to FIGS. 6 to 13.

Sidewall spacers 160_SW may be disposed on two opposing side surfaces of the lower source and drain pattern 150 in the second direction D2. For example, the sidewall spacers 160_SW may include a first sidewall spacer 162_SW and a second sidewall spacer 164_SW. The first sidewall spacer 162_SW may be in contact with a first side surface of the lower source and drain pattern 150 and define the first side surface. In addition, the second sidewall spacer 164_SW may be in contact with a second side surface of the lower source and drain pattern 150 and define the second side surface. The first side surface and the second side surface may be opposing sides of the lower source and drain pattern 150, and the first side surface and the second side surface may not be connected to each other. For example, the first side surface and the second side surface may be spaced apart from each other and may form opposite side surfaces of the lower source and drain pattern 150.

The first sidewall spacer 162_SW and the second sidewall spacer 164_SW may be independent structures. For example, each of the first sidewall spacer 162_SW and the second sidewall spacer 164_SW may be disposed in contact with respective one of both sides of the lower source and drain pattern 150 and may not be connected to each other. For example, the first sidewall spacer 162_SW and the second sidewall spacer 164_SW may be spaced apart from each other in the second direction D2. Accordingly, the sidewall spacers 162_SW and 164_SW may not be formed in an upper region including an upper surface of the lower source and drain pattern 150. For example, the first sidewall spacer 162_SW and the second sidewall spacer 164_SW may be disposed in contact with the first and second sides of the lower source and drain pattern 150, respectively, and the dielectric isolation layer 140 may be disposed in contact with the upper region including the upper surface of the lower source and drain pattern 150.

As illustrated in FIG. 3, heights of the first sidewall spacer 162_SW and the second sidewall spacer 164_SW may be lower than or equal to a height of the lower source and drain pattern 150. For example, the uppermost portions/surfaces of the first sidewall spacer 162_SW and the second sidewall spacer 164_SW may have a vertical level lower than or equal to the uppermost portion/surface of the lower source and drain pattern 150.

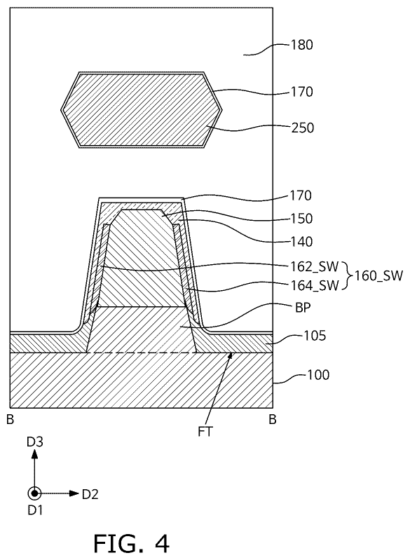

FIG. 4 illustrates another example of a cross-sectional view taken along line B-B of FIG. 1. Referring to FIG. 4, sidewall spacers 162_SW and 164_SW may be disposed/formed at an inclination the same as an inclination of a side surface of the lower pattern BP. For example, side surfaces of the sidewall spacers 162_SW and 164_SW may have the same angle with respect to a horizontal surface/line, e.g., in a cross-sectional view, as side surfaces of the lower pattern BP disposed below the corresponding side surfaces of the sidewall spacers 162_SW and 164_SW. The first sidewall spacer 162_SW and the second sidewall spacer 164_SW may be disposed at an inward inclination such that a width (e.g., a horizontal distance) between the first sidewall spacer 162_SW and the second sidewall spacer 164_SW, e.g., in a horizontal direction, decreases in a direction approaching a top of the first sidewall spacer 162_SW and the second sidewall spacer 164_SW. In this case, the first side surface of the lower source and drain pattern 150 may be formed to have the same inclination as the side surface of the first sidewall spacer 162_SW, e.g., the side surface contacting the lower source and drain pattern 150 and along the sidewall (e.g., the side surface) of the first sidewall spacer 162_SW, e.g., the side surface contacting the lower source and drain pattern 150. In addition, the second side surface of the lower source and drain pattern 150 may be formed at an inclination the same as an inclination of the side surface of the second sidewall spacer 164_SW, e.g., the side surface contacting the lower source and drain pattern 150 and along the sidewall (e.g., the side surface) of the second sidewall spacer 164_SW, e.g., the side surface contacting the lower source and drain pattern 150.

As described above, in the semiconductor device according to some aspects of the present disclosure, the sidewall spacers are disposed on both sides of the lower source and drain pattern to limit the shape of the side surfaces of the lower source and drain to correspond to a channel width of a corresponding transistor and/or to correspond to the lower channel pattern CP_B, thereby improving the integration and performance of the semiconductor device.

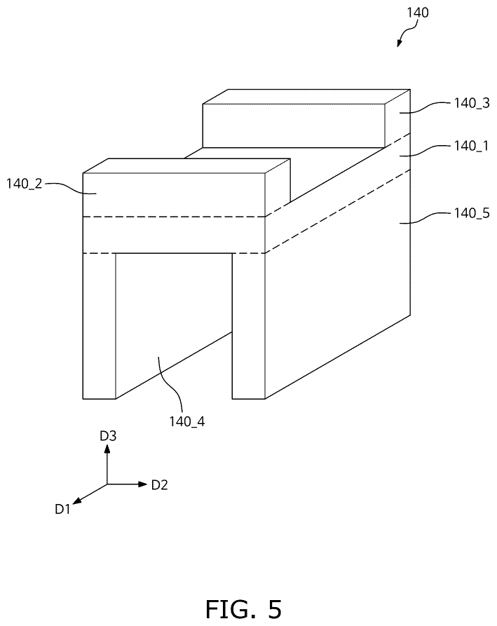

FIG. 5 is a diagram provided to explain a dielectric isolation layer according to some aspects of the present disclosure. Referring to FIGS. 2, 3, and 5, the dielectric isolation layer 140 may be disposed between the lower source and drain pattern 150 and the upper source and drain pattern 250 to separate and insulate the lower source and drain pattern 150 from the upper source and drain pattern 250. The dielectric isolation layer 140 may include first to fifth regions 140_1, 140_2, 140_3, 140_4, and 140_5. The first region 140_1 may face (e.g., contact) the upper surface of the lower source and drain pattern 150. The second region 140_2 may extend upward from a first end of the first region 140_1, and the third region 140_3 may extend upward from a second end spaced apart from the first end in the first direction D1. Outer sides/surfaces of the second region 140_2 and the third region 140_3 may be in contact with the gate insulating film 130, and inner sides/surfaces thereof may be in contact with an etching stop film 170. The fourth region 140_4 may extend downward from a third end connected to the first end and the second end of the first region 140_1. In addition, the fifth region 140_5 may extend downward from a fourth end opposite to the third end. Inner sides/surfaces of the fourth region 140_4 and the fifth region 140_5 may be in contact with the sidewall spacers 160_SW, and outer sides/surfaces thereof may be in contact with the etching stop film 170.

FIG. 5 illustrates that the fourth region 140_4 and the fifth region 140_5 extend from the first region 140_1 in a vertical direction, but the inventive concept is not limited thereto. For example, the fourth region 140_4 and the fifth region 140_5 may be formed to extend at an inclination along the sidewalls (e.g., the side surfaces) of the first sidewall spacer 162_SW and the second sidewall spacer 164_SW.

The dielectric isolation layer 140 may be formed such that a partial area thereof is disposed between the lower source and drain pattern 150 and the upper source and drain pattern 250 to support the upper source and drain pattern 250. The second region 140_2 and the third region 140_3 may extend from both ends (e.g., opposite ends) of the first region 140_1 along the lower gate electrode 120_B in the third direction D3 such that upper surfaces of the second region 140_2 and the third region 140_3 support (e.g., contact) the upper source and drain pattern 250.

The dielectric isolation layer 140 may be formed such that a partial area thereof isolates the lower source and drain pattern 150 and the upper source and drain pattern 250 from each other. For example, a portion of the dielectric isolation layer 140 may be interposed between the lower source and drain pattern 150 and the upper source and drain pattern 250. As described above, a lower surface of the lower source and drain pattern 150 may be in contact with the lower pattern BP. In addition, both sides of the lower source and drain pattern 150 opposite each other in the first direction D1 may contact the lower channel pattern CP_B and the lower gate electrode 120_B. In this case, the upper surface of the lower source and drain pattern 150 and both sides opposite each other in the second direction D2 are formed to be surrounded by (e.g., contact) the dielectric isolation layer 140, so that the lower source and drain pattern 150 and the upper source and drain pattern 250 may be electrically isolated/insulated from each other.

The dielectric isolation layer 140 may include at least one of silicon nitride (SiN), silicon nitride oxide (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. The dielectric isolation layer 140 may include a material different from that of the sidewall spacer 160_SW. Although it is illustrated that the dielectric isolation layer 140 is a single film, it is only for convenience of description, and the inventive concept is not limited thereto.

Referring again to FIGS. 1 to 3, the gate electrode 120 may extend lengthwise in the second direction D2 on the substrate 100. The gate electrode 120 may intersect the active pattern AP. The gate electrode 120 may be disposed on the lower pattern BP. The gate electrode 120 may be spaced apart from the adjacent gate electrode 120 in the first direction D1. The gate electrode 120 may surround the plurality of channel patterns CP. The gate electrode 120 may surround four surfaces of the channel pattern CP. For example, the gate electrode 120 may surround an upper surface, a lower surface, and both (e.g., opposite) side surfaces of the channel pattern CP. The upper and lower surfaces of the channel pattern CP may refer to the surfaces perpendicular to the third direction D3, and both/opposite side surfaces of the channel pattern CP may refer to the surfaces perpendicular to the second direction D2.

The gate electrode 120 may include an upper gate electrode 120_U and the lower gate electrode 120_B. The lower gate electrode 120_B may be disposed between adjacent channel patterns CP in the third direction D3. The lower gate electrode 120_B may be disposed between the lower pattern BP and the channel pattern CP that is disposed at the bottom of the plurality of channel patterns CP. The upper gate electrode 120_U may be disposed on the channel pattern CP that is disposed at the top of the plurality of channel patterns CP.

According to some aspects, the active pattern AP may include a plurality of channel patterns CP, and the gate electrode 120 may include a plurality of lower gate electrodes 120_B. In this case, the number of lower gate electrodes 120_B may be proportional to the number of channel patterns CP included in the active pattern AP. The number of lower gate electrodes 120_B may be equal to the number of channel patterns CP. For example, as illustrated in FIG. 2, the number of lower gate electrodes 120_B may be 4, which may be the same as the number of channel patterns CP. However, the inventive concept is not limited thereto.

The gate electrode 120 may include at least one of a metal, a metal alloy, a conductive metal nitride, a metal silicide, a doped semiconductor material, a conductive metal oxide, and a conductive metal oxynitride. For example, the gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but is not limited thereto. The conductive metal oxide and the conductive metal oxynitride may include an oxidized form of the materials described above, but are not limited thereto.

The gate insulating film 130 may be disposed between the gate electrode 120 and the plurality of channel patterns CP and between the gate electrode 120 and the source and drain pattern 150. For example, the gate insulating film 130 may be disposed between the upper gate electrode 120_U and the channel pattern CP (e.g., the top channel pattern of the upper channel patterns CP_U) that is disposed at the top of the plurality of channel patterns CP. The gate insulating film 130 may be disposed between the lower gate electrode 120_B and the channel pattern CP.

The gate insulating film 130 may extend in the first direction D1 along the upper and lower surfaces of the channel pattern CP. The sidewalls of the gate insulating film 130 may extend in the third direction D3 along the sidewalls of the source and drain patterns 150 and 250. The sidewalls of the gate insulating film 130 may be defined as a portion in contact with the source and drain patterns 150 and 250. The sidewalls of the source and drain patterns 150 and 250 may be defined as a portion in contact with the gate insulating film 130 and the channel pattern CP.

The gate insulating film 130 may include one or more of silicon oxide, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

A gate spacer 160_GS may be disposed on the upper gate electrode 120_U. For example, gate spacers 160_GS may extend, e.g., lengthwise, along the side surfaces of the upper gate electrode 120_U and the side surfaces of a gate capping pattern (not illustrated) disposed on the upper gate electrode 120_U. The gate spacers 160_GS may not be formed/positioned between the lower pattern BP and the channel pattern CP. The gate spacers 160_GS may not be formed/positioned between the adjacent channel patterns CP in the third direction D3.

For example, the gate spacer 160_GS may include at least one of silicon nitride (SiN), silicon nitride oxide (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. Although it is illustrated that the gate spacer 160_GS is a single film, it is only for convenience of description, and the inventive concept is not limited thereto.

In some aspects, the gate insulating film 130 may be disposed between the upper gate electrode 120_U and the channel pattern CP, and may not be disposed on the gate spacer 160_GS. For example, the gate insulating film 130 may not be disposed between the gate spacer 160_GS and the upper gate electrode 120_U, nor between the gate spacer 160_GS and the gate capping pattern. However, the inventive concept is not limited thereto.

Although not illustrated, a gate capping pattern may be disposed on the upper gate electrode 120_U. The gate capping pattern may cover an upper surface of the upper gate electrode 120_U. The gate capping pattern may overlap the upper gate electrode 120_U in the third direction D3. The gate capping pattern may be disposed between the gate spacers 160_GS. A side surface of the gate capping pattern may be in contact with the gate spacer 160_GS. An upper surface of the gate capping pattern may be disposed flush with (e.g., at the same level as) an upper surface of an interlayer insulating film 180. However, the inventive concept is not limited thereto.

For example, the gate capping pattern may include at least one of silicon nitride (SiN), silicon oxynitride (SiON), silicon carbon nitride (SiCN), silicon oxycarbonitride (SiOCN), and a combination thereof. The gate capping pattern may include a material having an etch selectivity with respect to the interlayer insulating film 180.

The etching stop film 170 may extend along the profiles of the sidewalls of the gate spacer 160_GS, the upper source and drain pattern 250, and the dielectric isolation layer 140. In addition, the etching stop film 170 may be disposed on the upper surface of the field insulating film 105.

The etching stop film 170 may include a material having an etching selectivity with respect to the interlayer insulating film 180. For example, the etching stop film 170 may include at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), and a combination thereof.

The interlayer insulating film 180 may be disposed on the etching stop film 170. The interlayer insulating film 180 may be disposed on the source and drain patterns 150 and 250. The interlayer insulating film 180 may be disposed on one side (or both sides) of the upper gate electrode 120_U. The interlayer insulating film 180 may be disposed between the upper gate electrodes 120_U. In addition, the interlayer insulating film 180 may be disposed on the upper surface of the field insulating film 105.

For example, the interlayer insulating film 180 may include at least one of silicon oxide (SiO), silicon nitride (SiN), silicon oxynitride (SiON), and a low dielectric constant material. For example, the low dielectric constant material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

Although not illustrated, the semiconductor device according to some aspects may further include a source and drain contact. The source and drain contact may be disposed on the lower source and drain pattern 150 and/or may be disposed on the upper source and drain pattern 250. The source and drain contact may extend through the interlayer insulating film 180 and the etching stop film 170. The source and drain contact may be electrically connected to the lower source and drain pattern 150 and/or may be electrically connected to the upper source and drain pattern 250.

The source and drain contact may include a conductive material. For example, the source and drain contact may include at least one of a metal, a metal nitride, a metal carbon nitride, a two-dimensional (2D) material, and a conductive semiconductor material.

FIGS. 6 to 13 are diagrams provided to explain a semiconductor device according to some embodiments of the present disclosure. For convenience of explanation, different configurations from those described with reference to FIGS. 1 to 5 will be mainly described. In the semiconductor device according to some embodiments, the lower source and drain pattern 150 and the upper source and drain pattern 250 may have different conductivity types. Additionally, at least one of the lower source and drain pattern and the upper source and drain pattern may include multiple epitaxial layers.

Referring to FIGS. 6 to 9, in the semiconductor device according to some embodiments, the lower source and drain pattern 150 may be an n-type lower source and drain pattern 150_N having an n-type conductivity. The n-type lower source and drain pattern 150_N may include at least one of phosphorus-doped silicon (Si:P), arsenic-doped silicon (Si:As), carbon-doped silicon (Si:C), arsenic and carbon-doped silicon (Si:As:C), arsenic and phosphorus-doped silicon (Si:As:P), and silicon (Si). However, the inventive concept is not limited thereto. On the other hand, the upper source and drain pattern 250 may be a p-type upper source and drain pattern 250_P having a p-type conductivity.

The p-type upper source and drain pattern 250_P may include at least one of silicon-germanium (SiGe), boron-doped silicon-germanium (SiGe:B), carbon-doped silicon-germanium (SiGe:C), carbon and boron-doped silicon-germanium (SiGe:C:B), boron-doped silicon (Si:B), and silicon (Si). However, the inventive concept is not limited thereto.

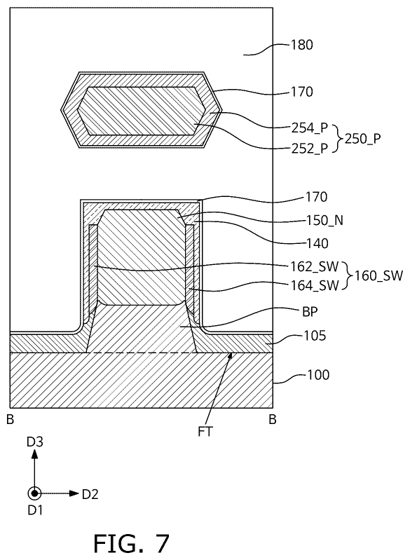

Referring to FIGS. 6 and 7, the p-type upper source and drain pattern 250_P may include a first epitaxial layer 252_P and a second epitaxial layer 254_P. The second epitaxial layer 254_P may extend along a profile of the first epitaxial layer 252_P. For example, the first epitaxial layer 252_P may be formed on and in contact with the upper channel pattern CP_U on both/opposite sides (left and right) of the first epitaxial layer 252_P, and the second epitaxial layer 254_P may be disposed to surround the first epitaxial layer 252_P that is not in contact with the upper channel pattern CP_U. In this case, the second epitaxial layer 254_P may extend along an outer surface of the first epitaxial layer 252_P so as not to be in contact with the adjacent upper channel pattern CP_U, but the inventive concept is not limited thereto. For example, in the cross section of FIG. 6, the first epitaxial layer 252_P may be in contact with the upper channel patterns CP_U on both/opposite sides of the first epitaxial layer 252_P, while a center region may have a concave cross section and/or a ribbon-shaped cross section, and the second epitaxial layer 254_P may be disposed on upper and lower surfaces of the first epitaxial layer 252_P. In the cross section of FIG. 7, the second epitaxial layer 254_P may be disposed to surround all of the upper and lower surfaces, and both side surfaces of the first epitaxial layer 252_P. The first epitaxial layer 252_P and the second epitaxial layer 254_P may include the same constituent material, and may have different concentrations of the constituent material. For example, each of the first epitaxial layer 252_P and the second epitaxial layer 254_P may include silicon-germanium (SiGe), and the concentration of germanium (Ge) in the second epitaxial layer 254_P may be greater than the concentration of germanium (Ge) in the first epitaxial layer 252_P.

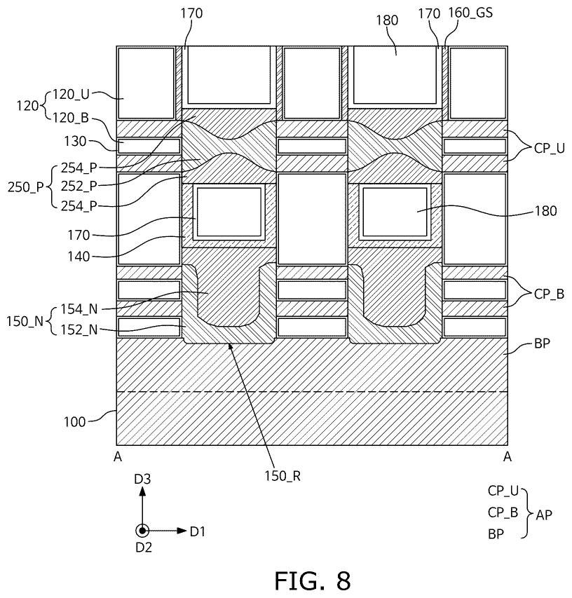

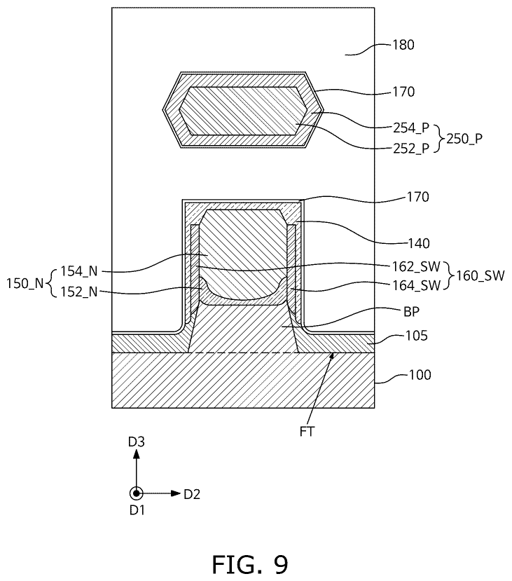

Referring to FIGS. 8 and 9, the n-type lower source and drain pattern 150_N may include a third epitaxial layer 152_N and a fourth epitaxial layer 154_N. The fourth epitaxial layer 154_N may be disposed on the third epitaxial layer 152_N. The third epitaxial layer 152_N may be disposed to surround/contact a lower surface of the fourth epitaxial layer 154_N and at least a part of a side surface of the fourth epitaxial layer 154_N. In this case, the third epitaxial layer 152_N and the fourth epitaxial layer 154_N may include the same constituent material, and may have different concentrations of the constituent material. For example, the third epitaxial layer 152_N and the fourth epitaxial layer 154_N may include silicon (Si) doped with arsenic (As) or phosphorus (P), and the concentration of arsenic (As) or phosphorus (P) included in the fourth epitaxial layer 154_N may be greater than the concentration of arsenic (As) or phosphorus (P) included in the third epitaxial layer 152_N.

Although FIGS. 8 and 9 illustrate that both the upper source and drain pattern 250_P and the lower source and drain pattern 150_N have multiple epitaxial layers, it is only for convenience of description, and the inventive concept is not limited thereto. For example, only one of the upper source and drain pattern 250_P and the lower source and drain pattern 150_N may have multiple epitaxial layers.

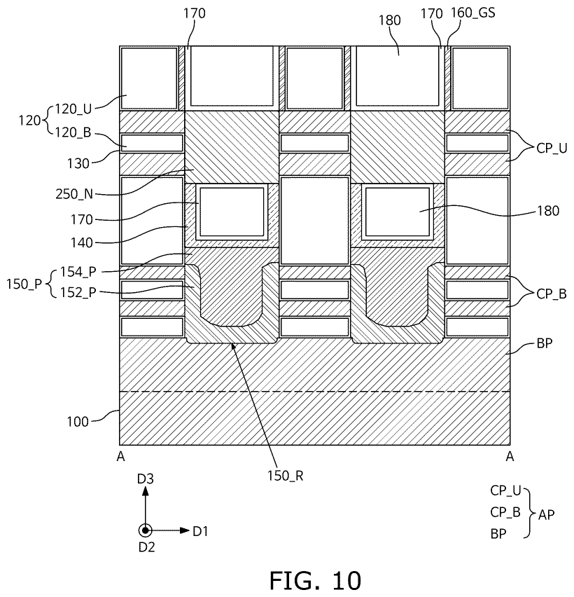

Referring to FIGS. 10 to 13, in the semiconductor device according to some aspects, the lower source and drain pattern 150 may be a p-type lower source and drain pattern 150_P having a p-type conductivity. The p-type lower source and drain pattern 150_P may include at least one of silicon-germanium (SiGe), boron-doped silicon-germanium (SiGe:B), carbon-doped silicon-germanium (SiGe:C), carbon and boron-doped silicon-germanium (SiGe:C:B), boron-doped silicon (Si:B), and silicon (Si). However, the inventive concept is not limited thereto.

On the other hand, the upper source and drain pattern 250 may be an n-type upper source and drain pattern 250_N having an n-type conductivity. The n-type upper source and drain pattern 250_N may include at least one of phosphorus-doped silicon (Si:P), arsenic-doped silicon (Si:As), carbon-doped silicon (Si:C), arsenic and carbon-doped silicon (Si:As:C), arsenic and phosphorus-doped silicon (Si:As:P), and silicon (Si). However, the inventive concept is not limited thereto.

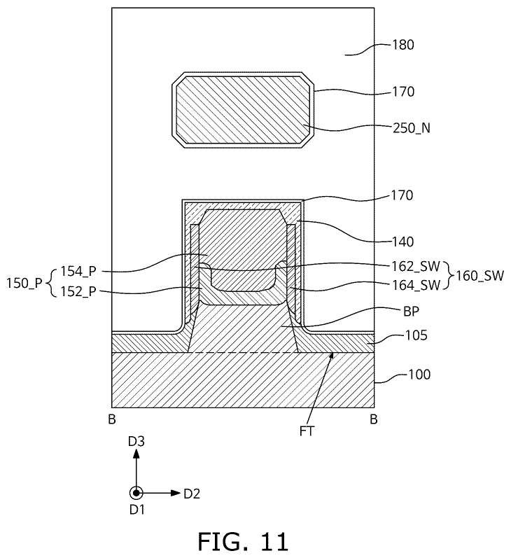

Referring to FIGS. 10 and 11, the p-type lower source and drain pattern 150_P may include a fifth epitaxial layer 152_P and a sixth epitaxial layer 154_P. The fifth epitaxial layer 152_P may be disposed in contact with the lower channel pattern CP_B and the lower pattern BP on both/opposite sides (left and right) of the fifth epitaxial layer 152_P, and the sixth epitaxial layer 154_P may be disposed on the fifth epitaxial layer 152_P. The fifth epitaxial layer 152_P may be disposed to surround a lower surface of the sixth epitaxial layer 154_P and at least a part of a side surface of the sixth epitaxial layer 154_P. In addition, at least a part of a side surface of the fifth epitaxial layer 152_P may be in contact with the sidewall spacer 160_SW, and at least a part of the side surface of the sixth epitaxial layer 154_P may also be in contact with the sidewall spacer 160_SW. In this case, as illustrated in the cross section of FIG. 11, the uppermost portion of the fifth epitaxial layer 152_P may have a vertical level corresponding to (e.g., the same as) a middle point between the uppermost portion and the lowermost portion of the sidewall spacer 160_SW. The fifth epitaxial layer 152_P and the sixth epitaxial layer 154_P may include the same constituent material, and may have different ratio of the constituent material. For example, the fifth epitaxial layer 152_P and the sixth epitaxial layer 154_P may include silicon-germanium (SiGe), and the concentration of germanium (Ge) in the sixth epitaxial layer 154_P may be greater than the concentration of germanium (Ge) in the fifth epitaxial layer 152_P.

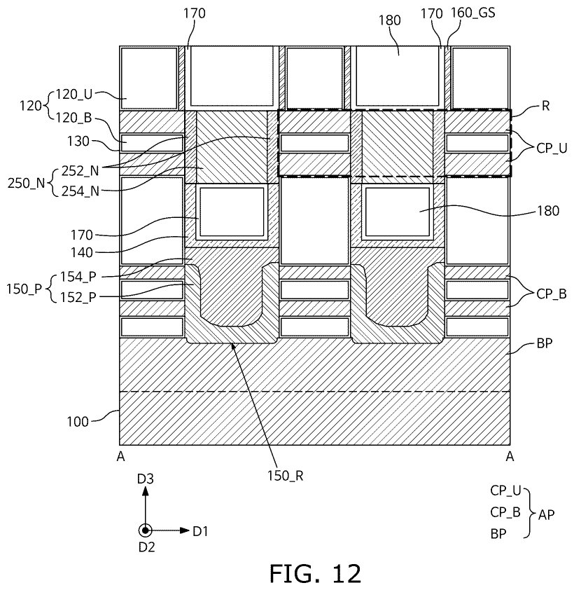

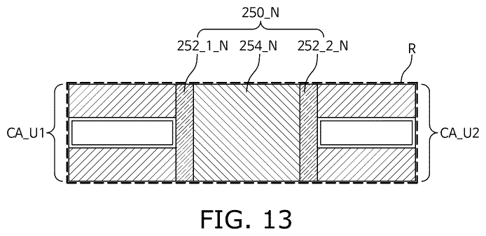

Referring to FIG. 12, the n-type upper source and drain pattern 250_N may include a seventh epitaxial layer 252_N and an eighth epitaxial layer 254_N. FIG. 13 is an enlarged view of a region R of FIG. 12. Referring to FIG. 13, the seventh epitaxial layer 252_N may include a (7-1)th epitaxial layer 252_1_N adjacent to a first upper channel pattern CA_U1 and a (7-2)th epitaxial layer 252_2_N adjacent to a second upper channel pattern CA_U2. The first upper channel pattern CA_U1 and the second upper channel pattern CA_U2 may be included in adjacent channel patterns, respectively. The eighth epitaxial layer 254_N may be disposed between the (7-1)th epitaxial layer 252_1_N and the (7-2)th epitaxial layer 252_2_N. The seventh epitaxial layer 252_N and the eighth epitaxial layer 254_N may include the same constituent material, and may have different concentrations of the constituent material. For example, the seventh epitaxial layer 252_N and the eighth epitaxial layer 254_N may include silicon (Si) doped with arsenic (As) or phosphorus (P), and the concentration of the arsenic (As) or phosphorus (P) in the eighth epitaxial layer 254_N may be greater than the concentration of the arsenic (As) or phosphorus (P) in the seventh epitaxial layer 252_N.

Although FIG. 12 illustrates that the (7-1)th epitaxial layer 252_1_N and the (7-2)th epitaxial layer 252_2_N are not connected to each other, the (7-1)th epitaxial layer 252_1_N and the (7-2)th epitaxial layer 252_2_N may be connected to each other and may form a ribbon-shaped cross section like the shape of the first epitaxial layer 252_P of FIG. 6 in certain embodiments. In addition, although FIG. 12 illustrates that both the upper source and drain pattern 250_N and the lower source and drain pattern 150_P have multiple epitaxial layers, it is only for convenience of description, and the inventive concept is not limited thereto. For example, only one of the upper source and drain pattern 250_N and the lower source and drain pattern 150_P may have multiple epitaxial layers.

As described above, in the semiconductor device according to some aspects of the present disclosure, a heavily doped epitaxial layer of a constituent material that applies strain to a channel pattern is formed to surround the outer side/surface of a lightly doped epitaxial layer of the same constituent material that connects adjacent channel patterns, so that it is possible to prevent defects caused by the heavily doped epitaxial layer contacting the channel pattern and to improve the performance of the semiconductor device.

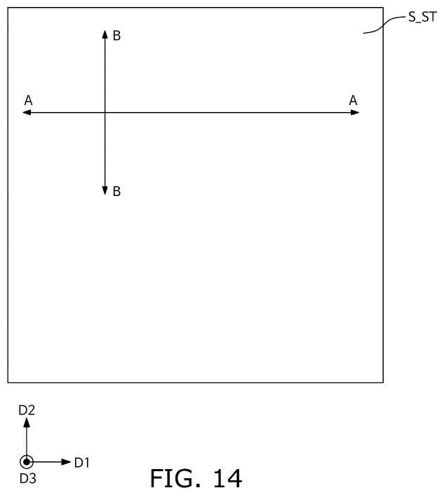

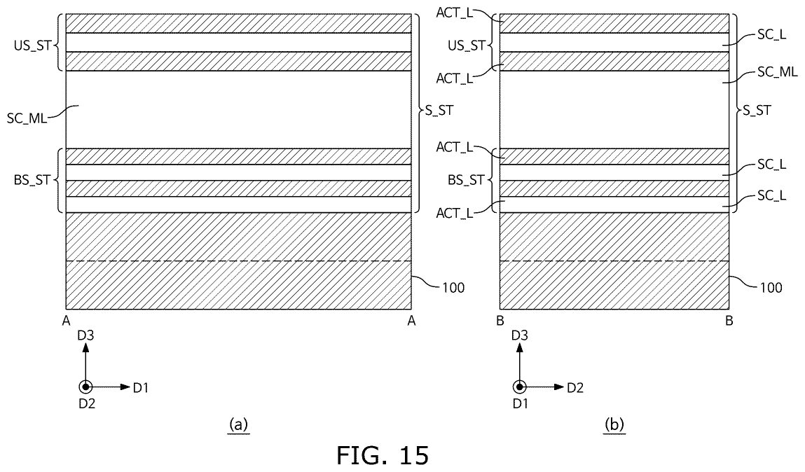

FIGS. 14 to 30 are diagrams showing intermediate stages, which are provided to explain a method for manufacturing a semiconductor device according to some aspects of the present disclosure. FIGS. 14, 16, and 18 are plan view diagrams showing intermediate stages of manufacturing a semiconductor device. FIGS. 15, 17 and 19 to 31 include FIGS. 15(a), 17(a), 19(a) to 31(a), 15(b), 17(b), and 19(b) to 31(b). FIGS. 15(a), 17(a), and 19(a) to 31(a) are partial cross-sectional views (e.g., A-A of FIGS. 1, 14, 16, and 18) of a semiconductor device in a length direction of a channel of the semiconductor device in intermediate stages of manufacturing the semiconductor device, and FIGS. 15(b), 17(b), and 19(b) to 31(b) are partial cross-sectional views (e.g., B-B of FIGS. 1, 14, 16, and 18) of a semiconductor device in a width direction of a channel of the semiconductor device in the intermediate stages of manufacturing the semiconductor device.

Referring to FIGS. 14 and 15, a method for manufacturing a semiconductor device according to some aspects may include forming a stack structure S_ST on the substrate 100.

The substrate 100 may be a silicon substrate, or may include other materials, such as silicon germanium (SiGe), silicon germanium on insulator (SGOI), indium antimony, lead tellurium compound, indium arsenic, indium phosphide, gallium arsenic, or gallium antimony, but is not limited thereto.

The stack structure S_ST may be formed on the substrate 100. The stack structure S_ST may include sacrificial semiconductor layers SC_L and active semiconductor layers ACT_L, which may be alternately stacked. As illustrated, the stack structure S_ST may include a stacked upper structure US-ST, an intermediate sacrificial semiconductor layer SC_ML, and a stacked lower structure BS-ST. The stacked upper structure US-ST may be defined as a stack structure of some of the active semiconductor layers ACT_L and some of the sacrificial semiconductor layers SC_L disposed on an upper portion of the intermediate sacrificial semiconductor layer SC_ML. The stacked lower structure BS-ST may be defined as a stack structure of some other of the active semiconductor layers ACT_L and some other of the sacrificial semiconductor layers SC_L disposed on a lower portion of the intermediate sacrificial semiconductor layer SC_ML. The active semiconductor layers ACT_L and the sacrificial semiconductor layers SC_L may be formed of materials having different etch rates from each other in a subsequent etching process. For example, the active semiconductor layers ACT_L and the sacrificial semiconductor layers SC_L may have etching selectivity with respect to an etchant used in a subsequent etching process.

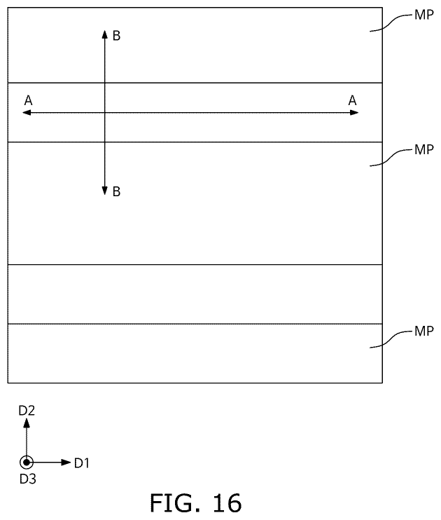

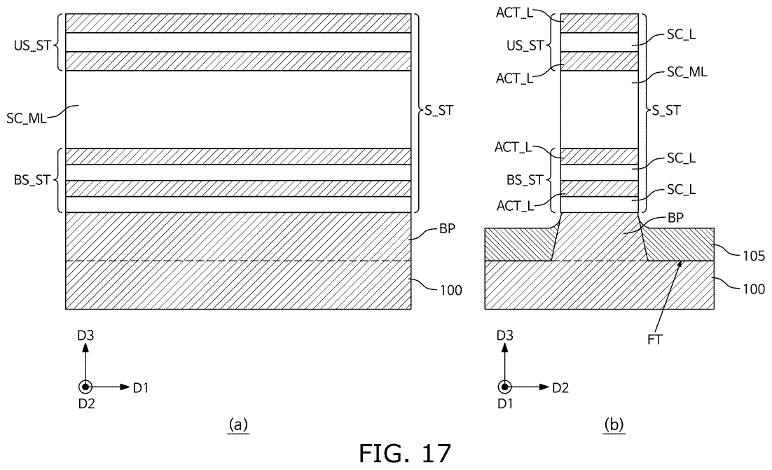

Referring to FIGS. 16 and 17, a method for manufacturing a semiconductor device according to some aspects may include patterning the stack structure S_ST. A mask pattern MP extending in the first direction D1 may be formed on the stack structure S_ST, and the stack structure S_ST may be patterned, i.e., selectively removed using the mask pattern MP as a mask. For example, the mask pattern MP may expose a part of an upper surface of the stack structure S_ST. The field trench FT and the lower pattern BP may be formed by selectively removing a region in which the mask pattern MP does not cover. The patterned stack structures S_ST may be spaced apart from each other in the second direction D2.

The field insulating film 105 may be formed on the field trench FT. The field insulating film 105 may fill the field trench FT. It is illustrated that the field insulating film 105 is a single film, but the inventive concept is not limited thereto.

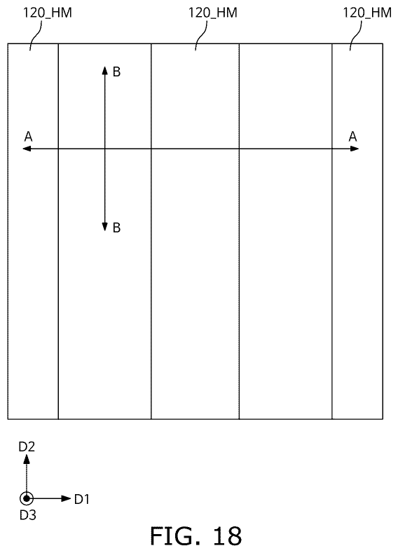

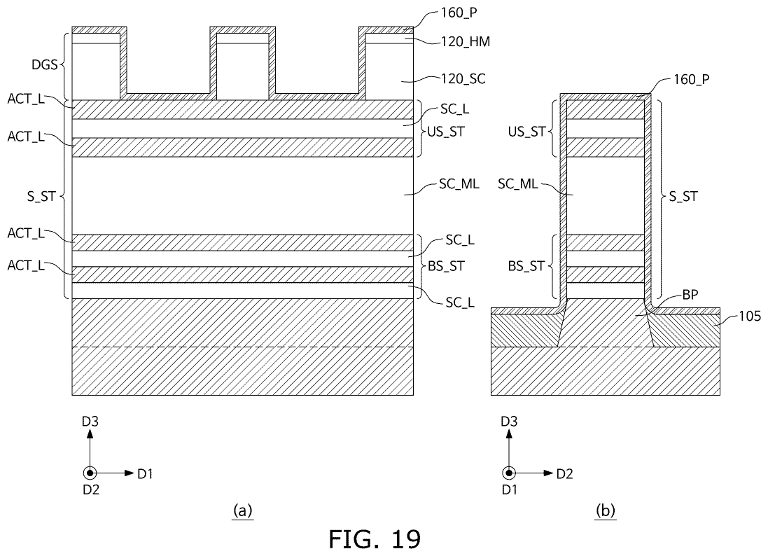

Referring to FIGS. 18 and 19, a dummy gate stack DGS may be formed on the stack structure S_ST. The dummy gate stack DGS may include a gate sacrificial pattern 120_SC and a hard mask pattern 120_HM. In order to form the dummy gate stack DGS, polysilicon may be formed on the stack structure S_ST, and the hard mask pattern 120_HM may be formed on the polysilicon. The gate sacrificial pattern 120_SC may be formed by patterning the polysilicon using the hard mask pattern 120_HM as a mask. In this case, the hard mask pattern 120_HM on the gate sacrificial pattern 120_SC may not be removed. The gate sacrificial pattern 120_SC may intersect the stack structure S_ST, e.g., in a plan view. For example, the gate sacrificial pattern 120_SC may cross the stack structure S_ST, e.g., perpendicularly. For example, the gate sacrificial pattern 120_SC may extend in the second direction D2, and the patterned stack structure S_ST may extend in the first direction D1.

A pre-liner layer 160_P may be formed on the dummy gate stack DGS and the stack structure S_ST. The pre-liner layer 160_P may be formed along a top surface and side surfaces of the hard mask pattern 120_HM, a side surface of the gate sacrificial pattern 120_SC, and the upper surface of the stack structure S_ST.

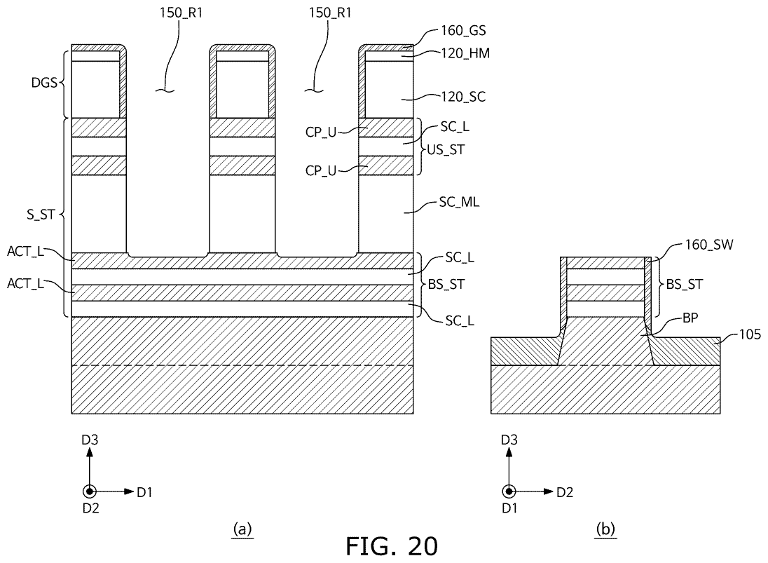

Referring to FIG. 20, an intermediate source and drain trench 150_R1 for forming the sidewall spacer 160_SW may be formed. For example, the intermediate source and drain trench 150_R1 may be formed by selectively etching portions of the upper stack structure US_ST and the intermediate sacrificial semiconductor layer SC_ML between adjacent dummy gate stacks DGS up to the upper end of the lower stack structure BS_ST, e.g., to expose a portion of the lower stack structure BS_ST.

The active semiconductor layers ACT_L of the upper stack structure US_ST may be separated by the intermediate source and drain trench 150_R1 to form the upper channel patterns CP_U. The intermediate source and drain trench 150_R1 may expose the upper channel patterns CP_U, the sacrificial semiconductor layer SC_L interposed between the upper channel patterns CP_U, and the intermediate sacrificial semiconductor layer SC_ML.

While the etching process is being performed, the thickness of the hard mask pattern 120_HM in the third direction D3 may decrease. In addition, a part of the pre-liner layer 160_P may be removed to form the gate spacer 160_GS and the sidewall spacer 160_SW.

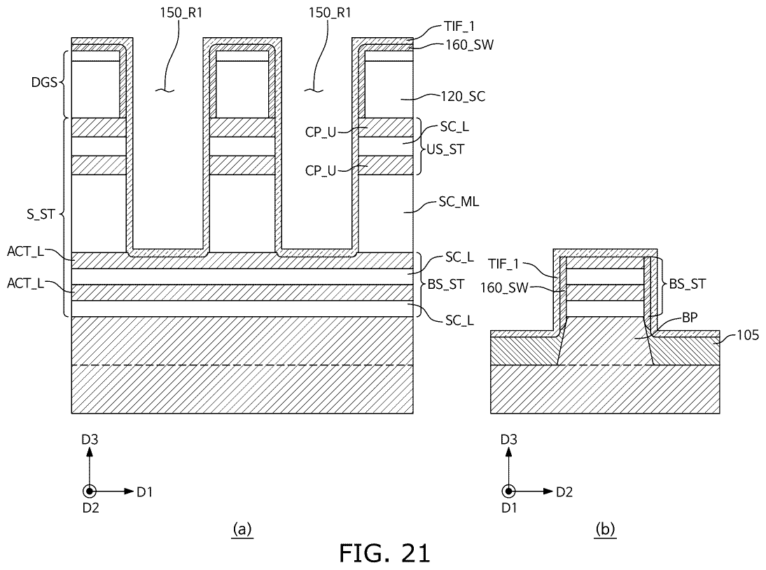

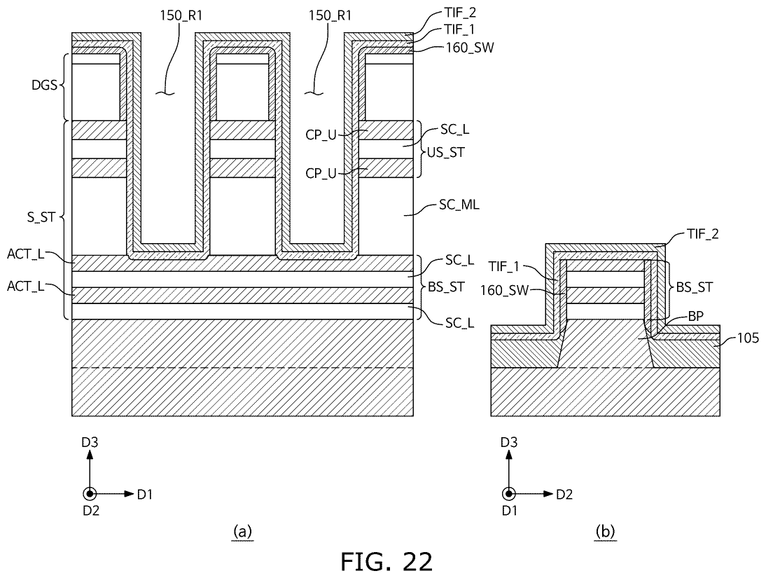

Referring to FIGS. 21 and 22, a first trench insulating film TIF_1 may be formed on the stack structure S_ST and the dummy gate stack DGS, and a second trench insulating film TIF_2 may be formed on the first trench insulating film TIF_1. The first trench insulating film TIF_1 may be a dielectric isolation layer (e.g., 140 of FIG. 3) for isolating the upper source and drain pattern and the lower source and drain pattern from each other. The second trench insulating film TIF_2 may be formed so as to protect the first trench insulating film TIF_1 in the process of forming the first trench insulating film TIF_1 as the dielectric isolation layer.

The material of the first trench insulating film TIF_1 may include at least one of silicon nitride (SiN), silicon nitride oxide (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. However, the inventive concept is not limited thereto.

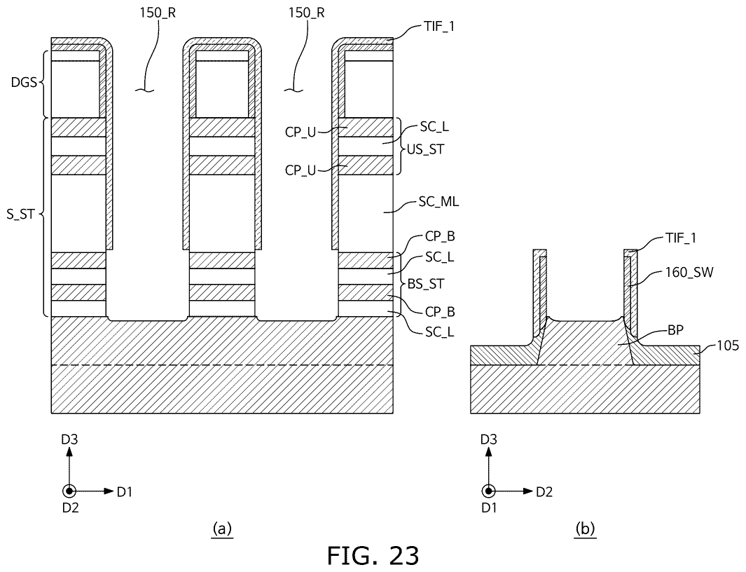

Referring to FIG. 23, the source and drain trench 150_R in which a source and drain pattern is disposed in a later step may be formed. For example, the source and drain trench 150_R may be formed by further etching the already formed intermediate source and drain trench 150_R1 to a lower end of the lower stack structure BS_ST, e.g., to expose a portion of the lower pattern BP.

The etching may include chemical oxide removal (COR) or pulsed dry cleaning (PDC). For example, for dry etching, ion beam etch (IBE), CF4 treatment, or chemical oxide removal (COR) may be used.

During the etching, portions of the second trench insulating film TIF_2 and the first trench insulating film TIF_1 may be removed. As a result of the etching, the first trench insulating film TIF_1 may remain on upper and side surfaces of the dummy gate stack DGS, and on side surfaces of the upper stack structure US_ST and the intermediate sacrificial semiconductor layer SC_ML. In addition, the lower stack structure BS_ST between adjacent dummy gate stacks DGS may be removed by the etching, but the sidewall spacer 160_SW and the first trench insulating film TIF_1 disposed on the side surfaces of the lower stack structure BS_ST may remain.

The active semiconductor layers ACT_L of the lower stack structure BS-ST may be separated by the source and drain trench 150_R to form the lower channel patterns CP_B. The source and drain trench 150_R may expose the lower channel patterns CP_B and the sacrificial semiconductor layer SC_L interposed between the lower channel patterns CP_B.

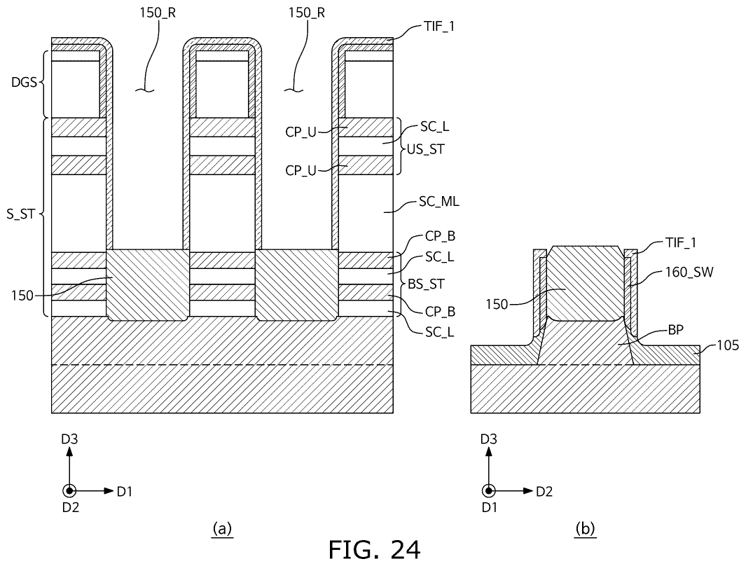

Referring to FIG. 24, the lower source and drain pattern 150 may be formed in the source and drain trench 150_R. For example, the lower source and drain pattern 150 may be formed using an epitaxial growth method. Sidewalls of the lower pattern BP and the lower channel pattern CP_B exposed by the source and drain trench 150_R may be used as a seed.

It is illustrated that the lower source and drain pattern 150 is a single layer in FIG. 24, but it may include multiple epitaxial layers in certain embodiments. When the lower source and drain pattern 150 includes multiple epitaxial layers, first, a lightly doped epitaxial layer including a constituent material such as germanium (Ge), arsenic (As), or phosphorus (P) bonded to silicon or doped to silicon in a low concentration may be formed using the sidewalls of the lower pattern BP and the lower channel pattern CP_B exposed by the source and drain trench 150_R as a seed, and then a heavily doped epitaxial layer of the same constituent material may be formed using the lightly doped epitaxial layer as a seed.

In some aspects, the lower source and drain pattern 150 may be formed using at least one of low-pressure chemical vapor deposition (LPCVD) process, selective epitaxial growth (SEG) process, or cyclic deposition and etching (CDE) process by using raw materials including an elemental semiconductor precursor.

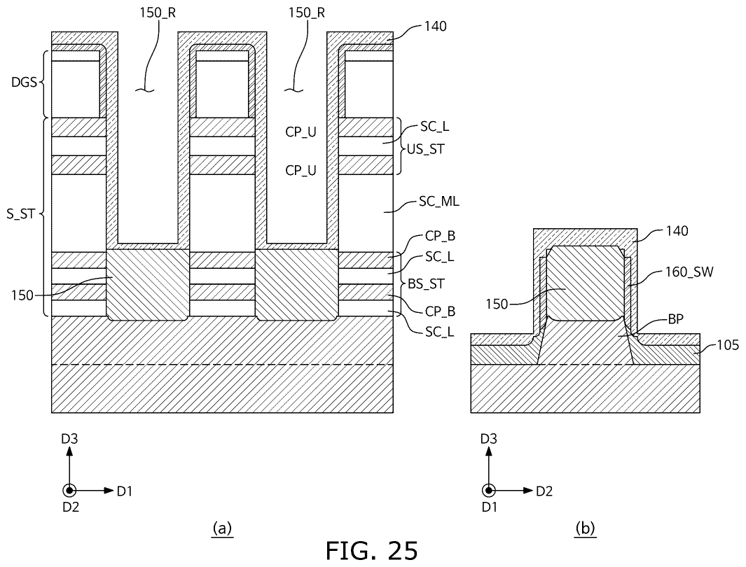

Referring to FIG. 25, the dielectric isolation layer 140 may be formed on the first trench insulating film TIF_1. In some aspects, the first trench insulating film TIF_1 and the dielectric isolation layer 140 may include the same or similar materials. In this case, as illustrated in FIG. 25, the first trench insulating film TIF_1 and the dielectric isolation layer 140 may be formed/integrated as a single layer. The dielectric isolation layer 140 may be formed on upper and side surfaces of the dummy gate stack DGS, side surfaces of the upper stack structure US_ST and the intermediate sacrificial semiconductor layer SC_ML, and upper surfaces of the lower source and drain pattern 150.

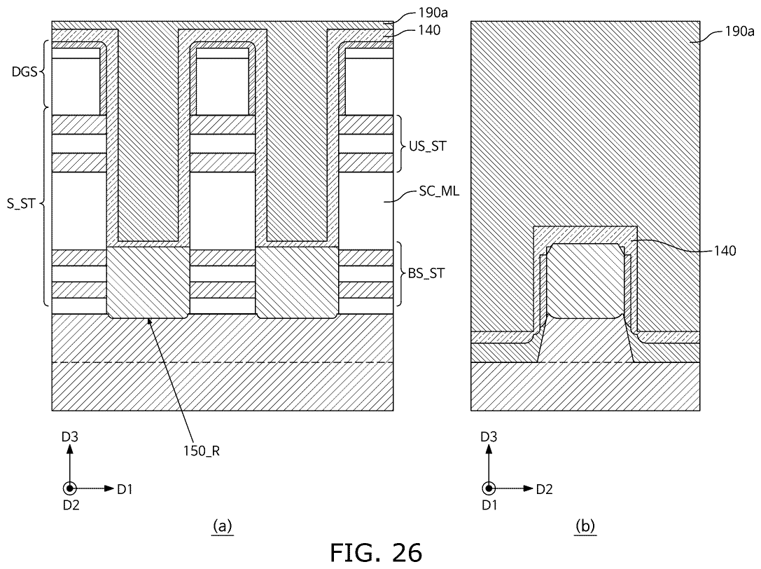

Referring to FIG. 26, a buried insulating layer 190a may be formed on the stack structure S_ST to limit an upper end position of the dielectric isolation layer 140 to a lower end height of the upper stack structure US_ST. For example, the buried insulating layer 190a may fill the source and drain trench 150_R. The buried insulating layer 190a may be formed on an upper surface of the dielectric isolation layer 140 disposed on the dummy gate stack DGS. After the buried insulating layer 190a is formed, an annealing process may be performed, and a planarization process such as chemical mechanical polishing (CMP) may be performed to remove excess materials. The material of a buried insulating layer 190a may include silicon oxide (SiO) and Tonen SilaZene (TOSZ). However, the inventive concept is not limited thereto.

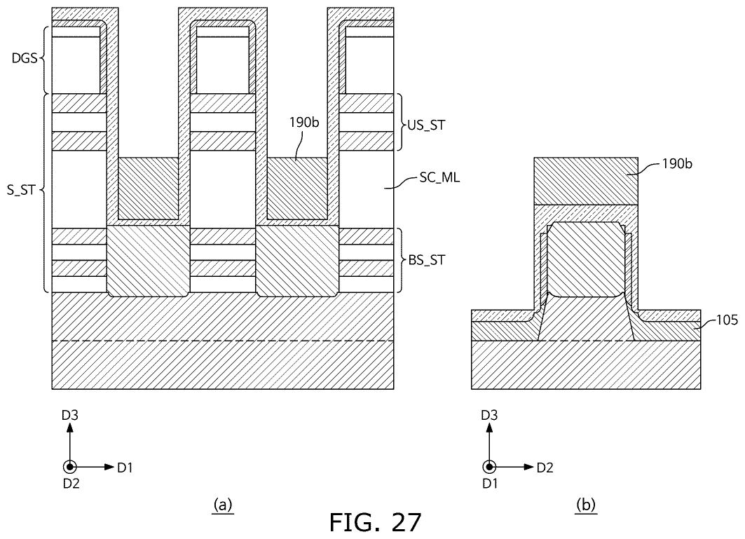

Referring to FIG. 27, a buried insulating layer 190b may be formed by etching the buried insulating layer 190a to an upper end height of the intermediate sacrificial semiconductor layer SC_ML. Pulsed dry cleaning (PDC) may be used for the etching process of the buried insulating layer 190b, but the inventive concept is not limited thereto. The buried insulating layer 190b may include silicon oxide, but is not limited thereto.

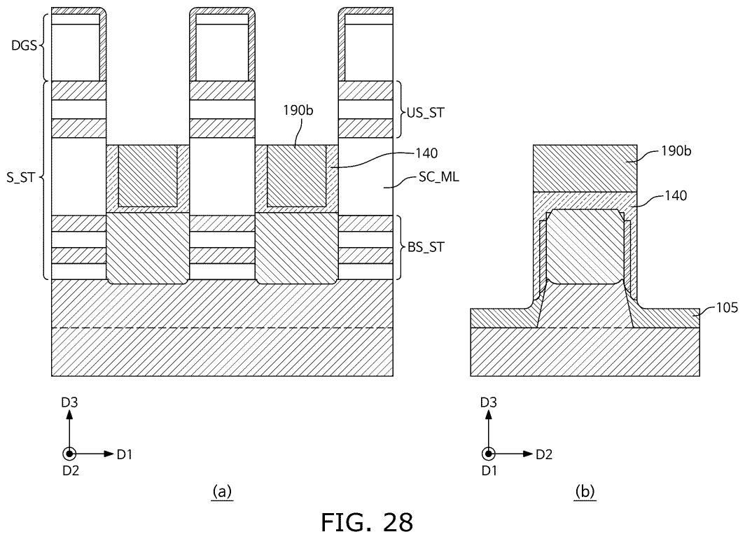

Referring to FIG. 28, the dielectric isolation layer 140 may be etched to an upper end height of the intermediate sacrificial semiconductor layer SC_ML. In this case, the upper surface of the etched dielectric isolation layer 140 may be substantially flush with (e.g., at the same level as) the upper surface of the etched buried insulating layer 190b. Wet etching may be used for the etching process of the dielectric isolation layer 140. By the wet etching, the dielectric isolation layer 140 may be isotropically etched. It is illustrated in FIG. 28 that the dielectric isolation layer 140 disposed on the field insulating film 105 is removed by the etching process, but the inventive concept is not limited thereto. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

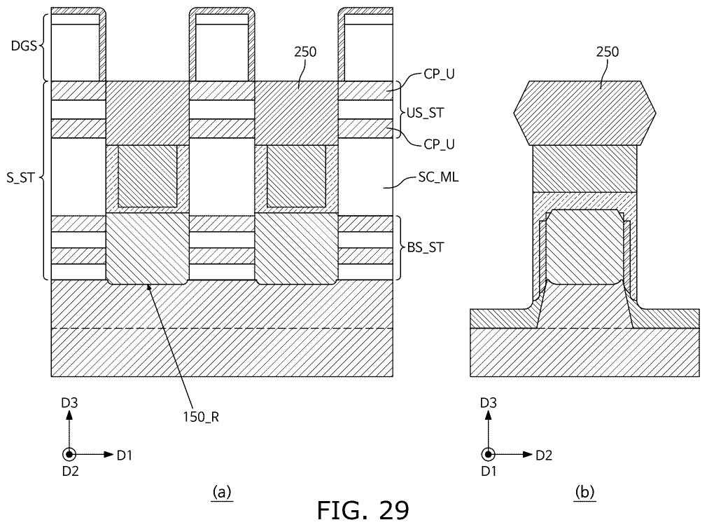

Referring to FIG. 29, the upper source and drain pattern 250 may be formed in the source and drain trench 150_R. For example, the upper source and drain pattern 250 may be formed using an epitaxial growth method. Sidewalls of the upper channel pattern CP_U exposed by the source and drain trench 150_R may be used as a seed.

Although it is illustrated that the upper source and drain pattern 250 is a single layer in FIG. 29, it may include multiple epitaxial layers in certain embodiments. When the upper source and drain pattern 250 includes multiple epitaxial layers, first, a lightly doped epitaxial layer including a low concentration of constituent material may be formed using the sidewalls of the upper channel pattern CP_U exposed by the source and drain trench 150_R as a seed, and then a heavily doped epitaxial layer including a high concentration of the same constituent material may be formed using the lightly doped epitaxial layer as a seed.

The lightly doped epitaxial layers grown on the sidewalls of both of the adjacent upper channel patterns CP_U may be connected to each other, and the heavily doped epitaxial layer of the same constituent material may be formed using the lightly doped epitaxial layer as a seed. The heavily doped epitaxial layer may be grown to extend along an outer surface of the lightly doped epitaxial layer. As a result, the heavily doped epitaxial layer may be formed to surround the outer surface of the lightly doped epitaxial layer.

In some aspects, the upper source and drain pattern 250 may be formed using at least one of low-pressure chemical vapor deposition (LPCVD) process, selective epitaxial growth (SEG) process, or cyclic deposition and etching (CDE) process by using raw materials including an elemental semiconductor precursor.

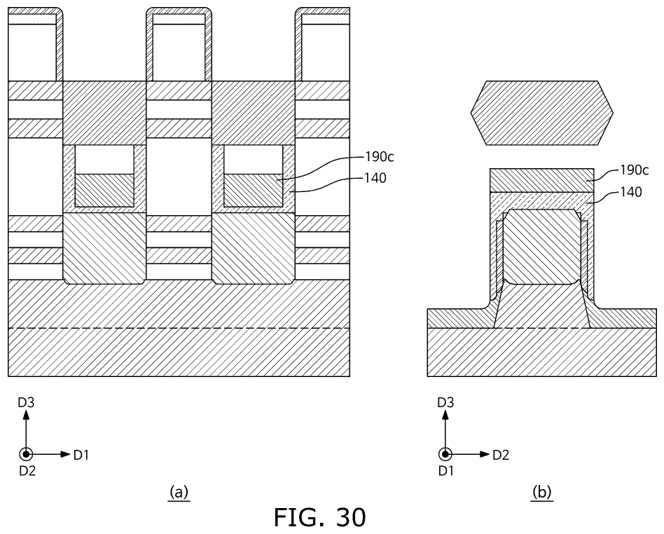

Referring to FIG. 30, a buried insulating layer 190c may be formed by partially or entirely removing the buried insulating layer 190b by a pre-cleaning process. For example, the buried insulating layer 190c may be formed when the buried insulating layer 190b is gradually removed by a pre-cleaning process occurring in the semiconductor device manufacturing process. In this case, unlike FIG. 29, the buried insulating layer 190c may be completely removed, or the height of the buried insulating layer 190c may be lower than the height of the upper surface of the dielectric isolation layer 140.

The etching stop film 170 (see FIG. 2) and the interlayer insulating film 180 (see FIG. 2) may be formed on the upper surfaces of the source and drain patterns 150 and 250 (see FIG. 29). The etching stop film 170 may be formed along the upper surface of the field insulating film 105 of FIG. 2 and the upper surface and side surfaces of the dielectric isolation layer 140 of FIG. 2. The interlayer insulating film 180 may be formed on the etch stop film 170.

The gate sacrificial pattern 120_SC of FIG. 29 may be removed, and the sacrificial semiconductor layers SC_L and SC_ML of FIG. 29 may be removed to form a gate trench. The gate trench may expose the channel patterns (CP_U and CP_B of FIG. 29) and the source and drain patterns 150 and 250. The gate insulating film 130 of FIG. 2 may be formed on the source and drain patterns 150 and 250 exposed by the gate trench, side surface of the dielectric isolation layer 140, and outer surface of the channel patterns CP. The gate electrode 120 (see FIG. 2) may be formed to surround the channel patterns CP. The gate electrode 120 may be disposed on the gate insulating film 130.

The gate electrode may include an upper gate electrode (120_U of FIG. 2) and a lower gate electrode (120_B of FIG. 2). For example, the upper gate electrode may be formed on the gate spacer 160_GS (see FIG. 2). The upper gate electrode may fill a space between adjacent gate spacers 160_GS. The lower gate electrode may be formed on the insulating film structure (e.g., on the gate insulating film 130). The lower gate electrode may fill a space between adjacent channel patterns CP.

The gate capping pattern may be formed on the upper gate electrode. For example, a part of the upper gate electrode may be recessed and the gate capping pattern may be formed on the upper surface of the upper gate electrode.

Each of the source and drain patterns 150 and 250 may be electrically connected to a power rail through a source contact and/or a drain contact. For example, a lower source contact, a lower drain contact, an upper source contact, and an upper drain contact may be formed on the source and drain patterns 150 and 250. Each contact may be electrically connected to the power rail through a contact via. A via may be formed in the lower pattern (BP of FIG. 2) such that a source and drain pattern 150 or 250 is electrically connected to a source contact or a drain contact, but the location where the via is formed is not limited thereto.

As a result, the semiconductor device as described above in FIGS. 1 to 13 may be provided.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Although the present disclosure has been described above by way of certain aspects and drawings, the inventive concept is not limited thereto, and it goes without saying that various changes and modifications can be made within the equivalent scope of the technical idea of the present disclosure and the claims to be described below by those of ordinary skill in the art.

What is claimed is:

1. A semiconductor device, comprising:
a substrate;
an active pattern including a plurality of channel patterns disposed on the substrate and vertically spaced apart from each other;
a gate electrode surrounding the plurality of channel patterns;
a lower source/drain pattern disposed on the substrate, and disposed on one side of the plurality of channel patterns;
an upper source/drain pattern spaced upward from the lower source/drain pattern; and
sidewall spacers including a first sidewall spacer in contact with a first side surface of the lower source/drain pattern and a second sidewall spacer in contact with a second side surface of the lower source/drain pattern, wherein the first side surface and the second side surface are opposing side surfaces of the lower source/drain pattern.

2. The semiconductor device according to claim 1, wherein the first sidewall spacer and the second sidewall spacer are disposed such that a horizontal distance between the first sidewall spacer and the second sidewall spacer decreases in a direction approaching a top of the first and second sidewall spacers.

3. The semiconductor device according to claim 1, wherein the first sidewall spacer and the second sidewall spacer are spaced apart from each other in a horizontal direction.

4. The semiconductor device according to claim 1, wherein the first sidewall spacer and the second sidewall spacer are not connected to each other.

5. The semiconductor device according to claim 1, wherein uppermost portions of the first sidewall spacer and the second sidewall spacer have a vertical level lower than or equal to an uppermost portion of the lower source/drain pattern.

6. The semiconductor device according to claim 1, further comprising a dielectric isolation layer isolating the lower source/drain pattern and the upper source/drain pattern from each other,
wherein the dielectric isolation layer is disposed on and in contact with an upper surface of the lower source/drain pattern, the first sidewall spacer, and the second sidewall spacer.

7. The semiconductor device according to claim 6, further comprising an interlayer insulating film disposed on the dielectric isolation layer and formed to fill a space between the lower source/drain pattern and the upper source/drain pattern.

8. The semiconductor device according to claim 1, wherein the sidewall spacers include at least one of silicon nitride, silicon oxycarbonitride, and silicon oxycarbide.

9. The semiconductor device according to claim 6, wherein the sidewall spacers and the dielectric isolation layer include different materials.

10. The semiconductor device according to claim 1, wherein the lower source/drain pattern and the upper source/drain pattern have different conductivity types.

11. The semiconductor device according to claim 1, wherein at least one of the lower source/drain pattern and the upper source/drain pattern includes multiple epitaxial layers.

12. A semiconductor device, comprising:
a substrate;
an active pattern including a lower pattern disposed on the substrate and a plurality of channel patterns spaced apart from each other, wherein the plurality of channel patterns include a lower channel pattern disposed on the lower pattern and a first upper channel pattern disposed on the lower channel pattern;
a gate electrode surrounding the lower channel pattern and the first upper channel pattern;
a lower source/drain pattern disposed on the lower pattern, and disposed on one side of the lower channel pattern;
an upper source/drain pattern disposed on one side of the first upper channel pattern; and
sidewall spacers disposed on two opposing side surfaces of the lower source/drain pattern,
wherein at least one of the lower source/drain pattern and the upper source/drain pattern includes multiple epitaxial layers.

13. The semiconductor device according to claim 12, wherein the lower source/drain pattern and the upper source/drain pattern have different conductivity types from each other.

14. The semiconductor device according to claim 13, wherein the lower source/drain pattern has an n-type conductivity,
the upper source/drain pattern has a p-type conductivity,
the upper source/drain pattern includes a first epitaxial layer and a second epitaxial layer, and
the first epitaxial layer is in contact with the channel patterns on both sides of the upper source/drain pattern, and the second epitaxial layer extends along an outer surface of the first epitaxial layer that is not in contact with the channel patterns.

15. The semiconductor device according to claim 13, wherein the lower source/drain pattern has an n-type conductivity,
the upper source/drain pattern has a p-type conductivity,
the lower source/drain pattern includes a first epitaxial layer and a second epitaxial layer,
the second epitaxial layer is disposed on the first epitaxial layer, and
the first epitaxial layer is disposed to surround at least a part of a lower surface of the second epitaxial layer and a side surface of the second epitaxial layer.

16. The semiconductor device according to claim 13, wherein the lower source/drain pattern has a p-type conductivity,
the upper source/drain pattern has an n-type conductivity,
the lower source/drain pattern includes a first epitaxial layer and a second epitaxial layer,
the first epitaxial layer is formed to be in contact with the channel patterns on both sides of the lower source/drain pattern and in contact with the lower pattern,
the second epitaxial layer is disposed on the first epitaxial layer,
the first epitaxial layer is disposed to surround at least a part of a lower surface of the second epitaxial layer and a side surface of the second epitaxial layer, and
at least a part of a side surface of the first epitaxial layer is in contact with the sidewall spacers and at least a part of a side surface of the second epitaxial layer is in contact with the sidewall spacers.

17. The semiconductor device according to claim 13, wherein the lower source/drain pattern has an n-type conductivity,
the upper source/drain pattern has a p-type conductivity,
the upper source/drain pattern includes a first epitaxial layer, a second epitaxial layer, and a third epitaxial layer,
the first epitaxial layer contacts the first upper channel pattern and the second epitaxial layer contacts a second upper channel pattern, wherein the first upper channel pattern and the second upper channel pattern are spaced apart in a horizontal direction, and
the third epitaxial layer is disposed between the first epitaxial layer and the second epitaxial layer.

18. The semiconductor device according to claim 13, further comprising a dielectric isolation layer disposed between the lower source/drain pattern and the upper source/drain pattern.

19. The semiconductor device according to claim 18, wherein the dielectric isolation layer includes:
a first region facing an upper surface of the lower source/drain pattern;
a second region extending upward from a first end of the first region;
a third region extending upward from a second end opposite to the first end of the first region;
a fourth region extending downward from a third end connected to the first end and the second end of the first region; and
a fifth region extending downward from a fourth end opposite to the third end, and
an upper surface of each of the second region and the third region faces a lower surface of the upper source/drain pattern.

20. A semiconductor device, comprising:
a substrate;
an active pattern including a lower pattern extending in a first direction and disposed on the substrate, and a plurality of channel patterns spaced apart from each other in a second direction perpendicular to the first direction, wherein each of the channel patterns includes a lower channel pattern disposed on the lower pattern and an upper channel pattern disposed on the lower channel pattern;
a gate electrode surrounding each of the lower channel pattern and the upper channel pattern;
a lower source/drain pattern disposed on the lower pattern, and disposed on at least one side of the lower channel pattern;
an upper source/drain pattern disposed on at least one side of the upper channel pattern;
a dielectric isolation layer isolating the lower source/drain pattern and the upper source/drain pattern from each other so that the lower source/drain pattern and the upper source/drain pattern are spaced apart from each other; and
sidewall spacers including a first sidewall spacer in contact with a first side surface of the lower source/drain pattern and defining the first side surface, and a second sidewall spacer in contact with a second side surface of the lower source/drain pattern and defining the second side surface, wherein the first side surface and the second side surface are opposing side surfaces of the lower source/drain pattern,
wherein the first sidewall spacer and the second sidewall spacer are disposed such that a horizontal distance between the first sidewall spacer and the second sidewall spacer decreases in a direction approaching a top of the first and second sidewall spacers,
the lower source/drain pattern and the upper source/drain pattern have different conductivity types, and
at least one of the lower source/drain pattern and the upper source/drain pattern includes multiple epitaxial layers.
